(19) United States
(12) Patent Application Publication
(10) Pub. No.: US 2008/0006824 A1
(43) Pub. Date: Jan. 10, 2008

(54) ELECTRODE CONNECTING MEMBER AND SURFACE LIGHT SOURCE BACKLIGHT UNIT HAVING THE SAME

(75) Inventors: Jae Sang LEE, Chungcheongnam-do (KR); Ki Hwan BAEK, Chungcheongnam-do (KR)

Correspondence Address: CANTOR COLBURN, LLP, 55 GRIFFIN ROAD SOUTH, BLOOMFIELD, CT, 06002, US

(73) Assignee: SAMSUNG ELECTRONICS CO., LTD., Gyeonggi-do (KR)

(21) Appl. No.: 11/775,429

(22) Filed: Jul. 10, 2007

(30) Foreign Application Priority Data
Jul. 10, 2006 (KR) 1020060064304

(51) Int. Cl. H01L 31/00

(52) U.S. Cl. 257/53

(57) ABSTRACT

The present invention relates to an electrode connecting member and a surface light source backlight unit having the same. The electrode connecting member includes a first coupling unit coupled to an end of a surface light source and a second coupling unit assembled to the first coupling unit. The first coupling unit includes a first body. The second connecting unit includes a second body arranged on the first body, a soldering portion connected to an electrode of the surface light source, and a compressing portion connected to a wire for applying a power to the surface light source.

This application claims priority to Korean Patent Application No. 10-2006-0064304 filed on Jul. 10, 2006 and all the benefits accruing therefrom under 35 U.S.C. §119, and the contents of which in its entirety are herein incorporated by reference.

### BACKGROUND OF THE INVENTION

1. Field of Invention

The present invention relates to an electrode connecting member and a surface light source backlight unit having the same, and more particularly, to an electrode connecting member including a compressing structure for stably connecting a power applying wire to an electrode of a surface light source backlight unit, and a surface light source backlight unit including the same.

2. Description of the Prior Art

A Liquid Crystal Display (“LCD”) controls its light transmission quantities according to image signals applied to a plurality of control switches arranged in a matrix pattern to display a desired image on its panel. As the LCD cannot provide a light by itself, it requires a light source such as a backlight. Backlight are classified into two types, namely an edge-type and a direct-type, depending on the position of the light source. The edge-type backlight installs its light source at an edge of an LCD panel such that the light emitted from the light source is irradiated to the LCD panel through a transparent light guide plate positioned below the LCD panel. The direct-type backlight has a plurality of light sources positioned below the LCD panel to directly irradiate a front surface of the LCD panel with light. However, such conventional light sources cause some loss of light due to optical members included in the light sources, such as a light guide plate, a diffuser plate and the like, resulting in diminished levels of light and deteriorated brightness uniformity.

One solution includes a backlight using a surface light source such as a flat fluorescent lamp. The flat fluorescent lamp includes an electrode coupled to a power supplying wire via a connection. The quality of this connection is important in order to ensure optimum efficiencies with respect to the transmission of power between the power source and the fluorescent lamp. Thus, if any deficiencies occur in the electrode connection, deterioration of the entire product may result due to bad lighting. Accordingly, the electrode connection requires high stability, and the assembling workability and productivity of the electrode connection should also be ensured for mass production.

### SUMMARY OF THE INVENTION

The present invention solves the aforementioned problems in the prior art. Exemplary embodiments of the present invention provide an electrode connection member, which has high stability and of which the assembling workability and productivity are ensured, and a surface light source backlight unit having the same.

According to an exemplary embodiment of the present invention, there is provided an electrode connecting member of a surface light source backlight unit. The electrode connecting member includes a first coupling unit coupled to an end of a surface light source and a second coupling unit assembled to the first coupling unit. The first coupling unit includes a first body. The second connecting unit includes a second body arranged on the first body, a soldering portion connected to an electrode of the surface light source, and a compressing portion connected to a wire for applying a power to the surface light source.

Preferably, the first coupling unit may be made of insulating material, and the second coupling unit may be made of conductive material.

The first body of the first coupling unit may be formed with a groove having a predetermined width and depth, and the second body of the second coupling unit may be arranged in the groove.

Preferably, the first body includes a first base plate, a first upper plate extending from a first end of the first base plate, and a first lower plate extending from a second end of the first base plate; and the second body includes a second base plate, a second upper plate extending from a first end of the second base plate, and a second lower plate extending from a second end of the second base plate.

Preferably, the soldering portion may include a first soldering portion and a second soldering portion, and the soldering portion may extend from respective ends of the second upper and lower plates of the second body.

Preferably, the compressing portion may extend from an end of the second base plate of the second body.

Alternatively, the first coupling unit may further include a first guide protruded from the first body guiding an assembling position of the second coupling unit, and the second coupling unit may be formed with a first guide hole for receiving the first guide.

The first coupling unit may further include a second guide formed at a side of the first body for guiding a coupling position of the surface light source and the first coupling unit.

The second guide may extend laterally from the side of the first body and include an end that is bent upwardly at an angle to face the side of the surface light source.

Alternatively, the electrode connecting member may further include a first fixing unit simultaneously wrapping and fixing the wire together with the compressing portion of the second coupling unit.

The first coupling unit may further include a reinforcing protrusion preparing a support for fixing the first fixing unit, and the second coupling unit may be formed with a reinforcing protrusion hole for receiving the reinforcing protrusion.

The electrode connecting member may further include a second fixing unit simultaneously wrapping and fixing the first fixing unit together with the reinforcing protrusion.

Preferably, the first fixing unit and the second fixing unit may be made of a flexible insulation material.

According to another aspect of the present invention, there is provided a surface light source backlight unit. The surface light source backlight unit includes a surface light source and at least one electrode connecting member connecting an electrode of the surface light source to a wire for applying a power to the surface light source. The electrode connecting member includes a first coupling unit coupled to a first end of the surface light source and a second coupling unit assembled to the first coupling unit. The first coupling unit includes a first body. The second connecting unit includes a second body arranged on the first body, a soldering portion connected to an electrode of the surface light source, and a compressing portion connected to the wire for applying a power to the surface light source.

Preferably, the surface light source may include a flat fluorescent lamp, and the flat fluorescent lamp may include a first substrate in which a plurality of discharge spaces are formed, a second substrate facing the first substrate, a sealing member for attaching the first and second substrates, and the electrode disposed on an end of the flat fluorescent lamp.

### BRIEF DESCRIPTION OF THE DRAWINGS

The above and other features and advantages of the present invention will become apparent from the following description of exemplary embodiments given in conjunction with the accompanying drawings, in which:

FIGS. 1A and 1B are respectively schematic perspective and side views showing a flat fluorescent lamp of a surface light source backlight unit according to an exemplary embodiment of the present invention;

FIG. 2 is a schematic perspective view showing an exemplary surface light source backlight unit including an exemplary electrode connecting member according to an exemplary embodiment of the present invention;

FIG. 3A is a schematic view showing exemplary first and second coupling units of an exemplary electrode connecting member according to a first exemplary embodiment of the present invention;

FIG. 3B is a perspective view illustrating the assemblage of the first and second coupling units with respect to the electrode connective member of FIG. 3A in accordance with the first exemplary embodiment of the present invention;

FIG. 3C is a perspective view of the exemplary electrode connecting member of FIG. 3A and flat fluorescent lamp to which the electrode connecting member is coupled in accordance with the first exemplary embodiment of the present invention;

FIG. 4A is a schematic perspective view of an exemplary electrode connecting member according to a second exemplary embodiment of the present invention;

FIG. 4B is a perspective view showing the electrode connecting member of FIG. 4A coupled to a flat fluorescent lamp in accordance with the second exemplary embodiment of the present invention;

FIG. 5 is a perspective view of an exemplary electrode connecting member coupled to a flat fluorescent lamp according to a third exemplary embodiment of the present invention; and

FIGS. 6A to 6C are perspective views showing an exemplary electrode connecting member coupled to a flat fluorescent lamp according to a fourth exemplary embodiment of the present invention.

### DETAILED DESCRIPTION OF THE PREFERRED EMBODIMENT

The invention will now be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present there between. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

Hereinafter, preferred embodiments of the present invention will be described in detail with reference to the accompanying drawings.

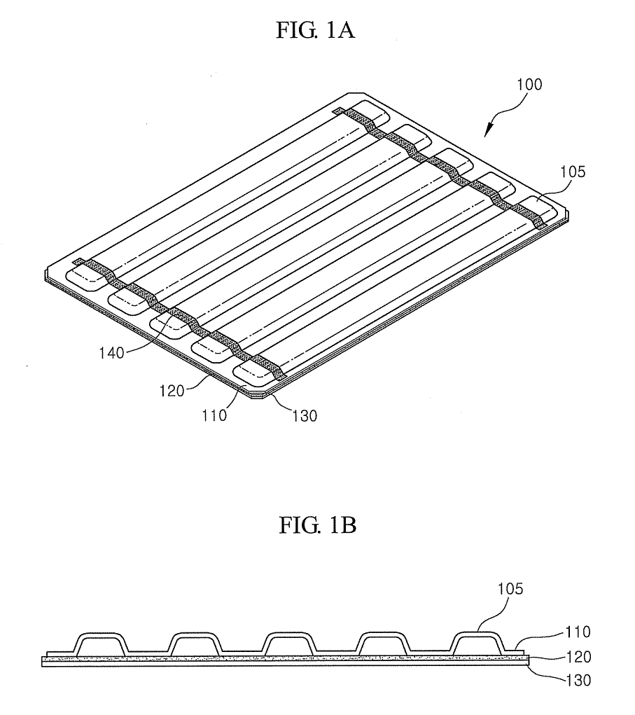

FIGS. 1A and 1B are respectively schematic perspective and side views of a flat fluorescent lamp of a surface light source backlight unit according to an exemplary embodiment of the present invention.

Referring to FIGS. 1A and 1B, a flat fluorescent lamp 100 includes a first substrate 110, a sealing member 120, a second substrate 130 and electrodes 140. A plurality of discharge spaces 105 is formed in the first substrate 110 to extend in parallel with each other. The first and second substrates 110 and 130 are arranged to face each other, and then they are coupled by means of the sealing member 120. The first and second substrates 110 and 130 are made of transparent insulation material, for example include glass substrates. A fluorescent layer (not shown) is formed on the insides of the first and second substrates 110 and 130, respectively. The electrodes 140 include a portion through which power is applied to the flat fluorescent lamp 100. The electrodes 140 are formed on opposite ends of the first substrate 110, and also formed on opposite ends of the second substrate 130 (not shown) facing the first substrate 110, respectively.

In the flat fluorescent lamp 100, the voltage applied from the outside through the electrodes 140 causes plasma discharge to be generated in the respective discharge spaces 105. Ultraviolet (“UV”) rays generated by the plasma discharge are converted into visible rays by passing through the fluorescent layer formed on the insides of the flat fluorescent lamp 100 and are then emitted out of the flat fluorescent lamp 100.

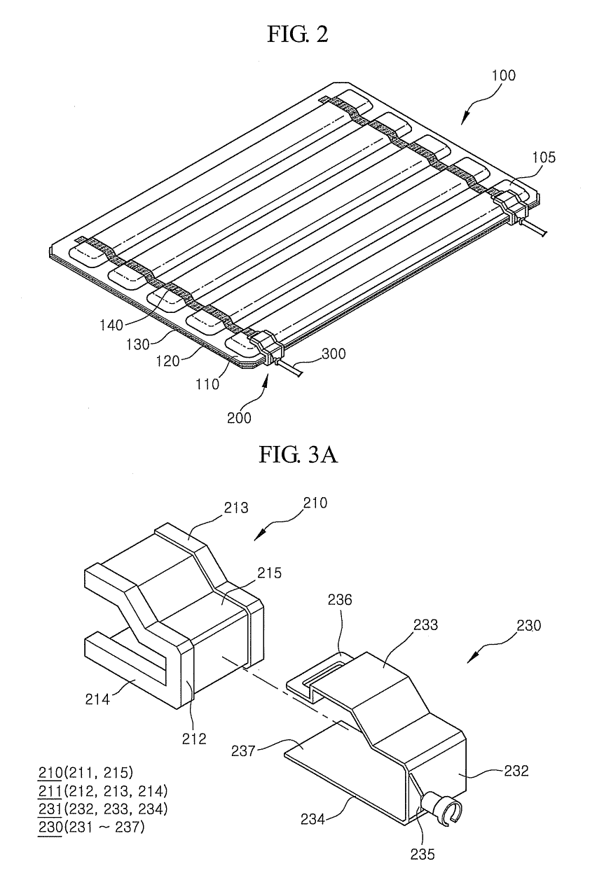

FIG. 2 is a schematic perspective view showing an exemplary surface light source backlight unit having an exemplary electrode connecting member connected thereto according to an exemplary embodiment of the present invention.

Referring to FIG. 2, the surface light source backlight unit includes the flat fluorescent lamp 100, electrode connecting members 200 and wires 300.

The electrodes 140 are formed on opposite ends of the upper and lower surfaces (i.e., first and second substrates 110 and 130) of the flat fluorescent lamp 100 in parallel with each other. Each of the electrodes 140 and the wires 300 are electrically and mechanically connected by means of the corresponding electrode connecting member 200. The electrodes 140 are arranged to connect a plurality of discharge tubes, i.e., the discharge spaces 105, in parallel. As shown in FIG. 2, the electrodes 140 are formed along the surfaces of the first and second substrates 110 and 130, respectively, of the flat fluorescent lamp 100. Alternatively, the electrodes 140 may be formed on the inner surfaces of the first and second substrates 110 and 130, respectively, and portions of the electrodes 140 soldered to the electrode connecting members 200 may be formed on the outsides of the first and second substrates 110 and 130, respectively.

The electrode connecting members 200 are respectively coupled to the electrodes 140 formed on the flat fluorescent lamp 100 at the corresponding positions. That is, the electrode connecting members 200 are respectively coupled to left and right lower ends of the flat fluorescent lamp 100, and first ends of the respective electrode connecting members 200 are soldered to the electrodes 140, and the other ends, or second ends, of the respective electrode connecting members 200 are connected to the wires 300, so that the voltage provided through the wires 300 is applied to the electrodes 140. Hereinafter, the electrode connecting member 200 will be described in more detail.

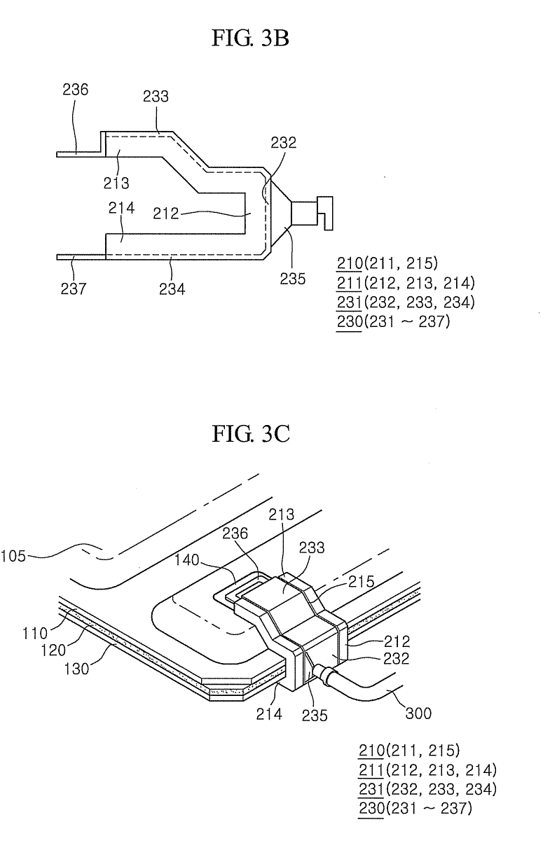

FIG. 3A is a schematic view showing first and second coupling units of an exemplary electrode connecting member 200 according to a first exemplary embodiment of the present invention, FIG. 3B is a perspective view illustrating the assemblage of the first and second coupling units together according to the first exemplary embodiment, and FIG. 3C is a perspective view of the exemplary electrode connecting member coupled to a flat fluorescent lamp according to the first exemplary embodiment of the present invention.

Referring to FIGS. 3A to 3C, the electrode connecting member 200 includes a first coupling unit 210 and a second coupling unit 230. In exemplary embodiments, the first coupling unit 210 is coupled to an end of the flat fluorescent lamp 100, and the second coupling unit 230 is assembled to the first coupling unit 210. Preferably, the first coupling unit 210 may be made of insulating material and the second coupling unit 230 may be made of conductive material.

The first coupling unit 210 includes a first body 211, which is configured to partially wrap a surface of the first and second substrates 110 and 130, respectively, and a side surface of the flat fluorescent lamp 100.

The first body 211 includes a first base plate 212 formed vertically to face the side surface of the flat fluorescent lamp 100, a first upper plate 213 extending from an end (first end) of the first base plate 212 and formed to face the first substrate 110 of the flat fluorescent lamp 100, and a first lower plate 214 extending from the other end (second end) of the first base plate 212 and formed to face the second substrate 130. In an exemplary embodiment, the first upper plate 213 is formed to be curved corresponding to the shape of the first substrate 110 to include the discharge space 105 formed thereon. In addition, the first base, upper and lower plates 212, 213 and 214, respectively, of the first body 211 may be formed integrally with one another.

The second coupling unit 230 includes a second body 231 arranged on the first body 211, soldering portions 236 and 237 connected to the electrodes 140 of the flat fluorescent lamp 100, and a compressing portion 235 connected to an end of the wire 300 through which the power is applied to the electrodes 140 of the flat fluorescent lamp 100.

The second body 231 of the second coupling unit 230 is formed corresponding to the shape of the first body 211, and thus assembled to the first body 211. The first body 211 may be formed with a groove 215 having predetermined width and depth, preferably corresponding to the width and thickness of the second body 231. The second body 231 may then be arranged on, and assembled to, the groove 215.

The second body 231 includes a second base plate 232 facing the first base plate 212 of the first coupling unit 210, a second upper plate 233 extending from an end (first end) of the second base plate 232 to face the first upper plate 213 of the first coupling unit 210, and a second lower plate 234 extending from the other end (second end) of the second base plate 232 to face the first lower plate 214 of the first coupling unit 210.

The soldering portion includes a first soldering portion 236 and a second soldering portion 237. The first soldering portion 236 extends from an end (first end) of the second upper plate 233 of the second body 231 and the second soldering portion 237 extends from an end (first end) of the second lower plate 234, so that the first and second soldering portions 236 and 237 are respectively soldered to the electrodes 140 formed on the first and second substrates 110 and 130, respectively.

The compressing portion 235 extends from a side of the second base plate 232 of the second body 231. An end of the compressing portion 235 is formed in a partially-opened ring shape so as to fix the wire 300 thereto by compressing the wire 300. Alternatively, the end of the compressing portion 235 may be formed in a two-ring shape so as to compress a sheath and a core of the wire 300 respectively. Alternatively, the end of the compressing portion 235 may be formed in a single-ring shape so as to compress only the core of the wire 300. Alternatively, the end of the compressing portion 235 may be formed in a plate shape before the wire 300 is connected to the end of the compressing portion 235. When a mechanical force is applied to surround the wire 300 after the wire 300 is positioned on the end of the compressing portion 235, the end of the compressing portion 235 is reformed into the shape of the wire 300 as shown in FIG. 3. Alternatively, the second body 231, the soldering portions 236 and 237, and the compressing portion 235 of the second coupling unit 230 may be formed integrally with one another.

Although it has been illustrated in this embodiment that the first and second coupling units 210 and 230 are coupled to an end of the flat fluorescent lamp 100 on which the electrode 140 is formed, the present invention is not limited thereto. For example, the first and second coupling units 210 and 230 may be coupled to an end of the flat fluorescent lamp 100 and spaced apart from the electrode 140 by a predetermined distance, and the soldering portions 236 and 237 of the second coupling unit 230 extend by a predetermined length to be connected to the electrode 140.

By connecting the electrode 140 of the flat fluorescent lamp 100 to the wire 300 using the electrode connecting member 200 consisting of the first and second coupling units 210 and 230, respectively, as mentioned above, the reliability of the electrode connection may be enhanced and the assembling workability and productivity may be improved.

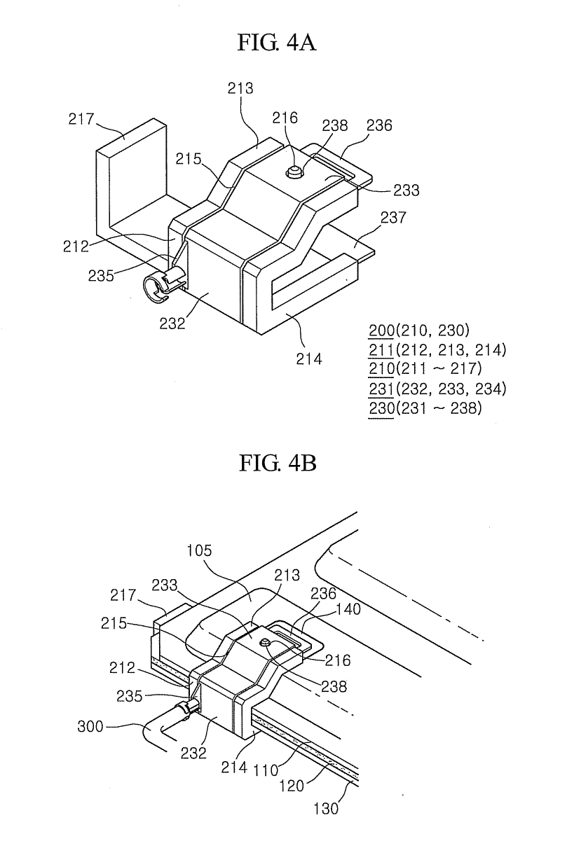

FIG. 4A is a schematic perspective view of an exemplary electrode connecting member according to a second exemplary embodiment of the present invention, and FIG. 4B is a perspective view of the exemplary electrode connecting member of FIG. 4A coupled to a flat fluorescent lamp.

The second exemplary embodiment shown in FIGS. 4A and 4B is substantially similar to the first embodiment, except that first and second guides are additionally formed in the first coupling unit 210. Hereinafter, the second embodiment will be explained based on these differences.

The electrode connecting member 200 includes a first coupling unit 210 and a second coupling unit 230. The first coupling unit 210 is coupled to an end of the flat fluorescent lamp 100, and the second coupling unit 230 is assembled to the first coupling unit 210. Preferably, the first coupling unit 210 is made of insulating material, and the second coupling unit 230 is made of conductive material.

The first coupling unit 210 includes a first body 211, a first guide 216, and a second guide 217.

The first body 211 includes a first base plate 212, a first upper plate 213, and a first lower plate 214. The first body 211 is formed to partially wrap a surface of the first and second substrates 110 and 130 of the flat fluorescent lamp 100 and a side of the flat fluorescent lamp. The first body 211 is formed with a groove 215 having a width and depth corresponding to the width and thickness of a second body 231.

The first guide 216 protrudes from the first upper plate 213 of the first body 211 by a predetermined height in order to guide an assembling position of the second coupling unit 230. As shown in FIGS. 4A-4B, the first guide 216 is disposed on the groove portion 215 of the first upper plate 213.

In addition, the second guide 217 is formed at a side of the first lower plate 214 of the first body 211 in order to guide a coupling position of the first coupling unit 210 with respect to the flat fluorescent lamp 100. The second guide 217 extends from the side of the first lower plate 214 in a lateral direction of the flat fluorescent lamp 100. An end of the second guide 217 is bent at an upward angle and formed to face the side of the flat fluorescent lamp 100, thus being generally formed in an “L” shape. Alternatively, the first body 211, the first guide 216 and the second guide 217 may be formed integrally with one another.

The second coupling unit 230 includes a second body 231 arranged on the first body 211, soldering portions 236 and 237 connected to the electrode 140 of the flat fluorescent lamp 100, and a compressing portion 235 connected to an end of the wire 300 through which the power is applied to the electrode 140 of the flat fluorescent lamp 100.

The second body 231 includes a second base plate 232, a second upper plate 233, and a second lower plate 234. The second upper plate 233 is formed with a first guide hole 238 to be coupled with the first guide 216.

By forming the first guide 216 and the first guide hole 238 in the respective first body 211 and second body 231, the arrangement of the second body 231 on the first body 211 is facilitated, thereby ensuring better assembling workability. In addition, the formation of the second guide 217 facilitates the coupling of the first coupling unit 210 to the flat fluorescent lamp 100 via a respective coupling position defined by the second guide 217, thereby also ensuring better assembling workability.

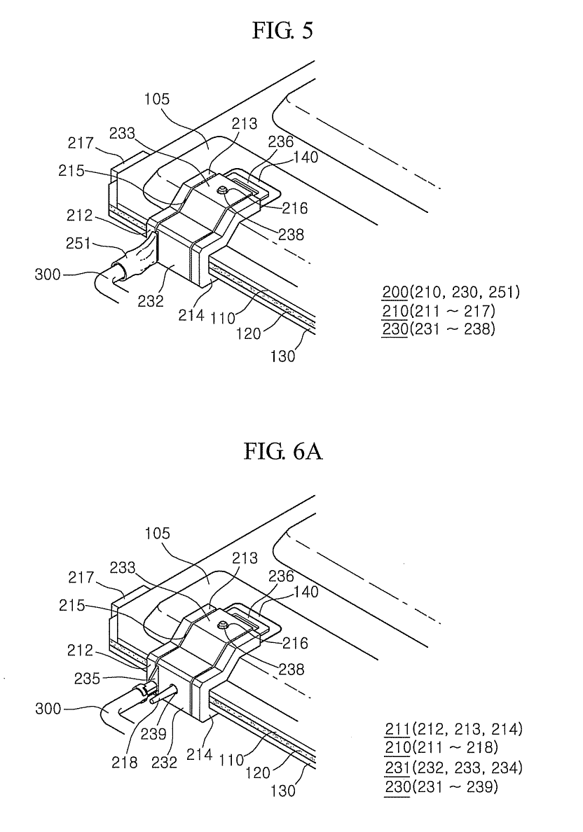

FIG. 5 is a perspective view of an exemplary electrode connecting member coupled to a flat fluorescent lamp according to a third exemplary embodiment of the present invention.

The third exemplary embodiment shown in FIG. 5 is substantially similar to the former embodiments, except that it additionally includes a first fixing unit. Hereinafter, this embodiment will be explained based on this difference.

The electrode connecting member 200 includes a first coupling unit 210, a second coupling unit 230 and a first fixing unit 251. The first coupling unit 210 is coupled to an end of the flat fluorescent lamp 100, and the second coupling unit 230 is assembled to the first coupling unit 210. Preferably, the first coupling unit 210 is made of insulating material, and the second coupling unit 230 is made of conductive material.

The first coupling unit 210 includes a first body 211, a first guide 216 for guiding an assembling position of the second coupling unit, and a second guide 217 for guiding a coupling position of the first coupling unit 210.

The second coupling unit 230 includes a second body 231 arranged on the first body 211, soldering portions 236 and 237 connected to the electrode 140 of the flat fluorescent lamp 100, and a compressing portion 235 connected to an end of the wire 300 through which the power is applied to the electrode 140 of the flat fluorescent lamp 100. The second body 231 is formed with a first guide hole 238 to be coupled to the first guide 216.

The first fixing unit 251 simultaneously wraps and securely fixes the compressing portion 235 of the second coupling unit 230 and the wire 300. The first fixing unit 251 is preferably made of a flexible insulation material. In this exemplary embodiment, a thermally-shrinkable insulation tube is used as the first fixing unit 251. By positioning the first fixing unit 251 to completely wrap an end of the wire 300 and the compressing portion 235 and then applying heat thereto, the first fixing unit 251 shrinks and becomes firmly secured to the end of the wire 300 and the compressing portion 235 as shown in FIG. 5.

Thus, the installation of the thermally-shrinkable insulation tube as described above, may prevent separation and deviation of the wire 300 from the compressing portion 235 of the second coupling unit 230 by external impacts or vibrations, thereby further improving reliability of the wire connection.

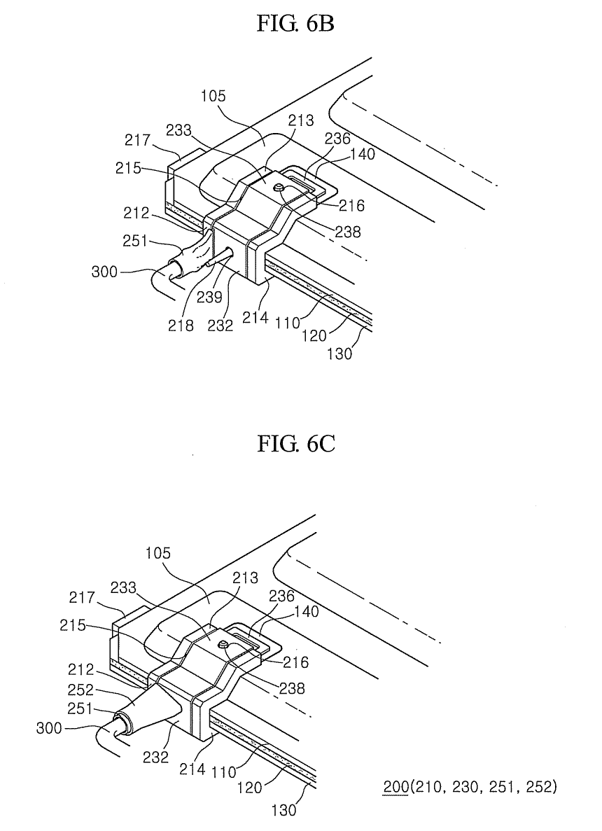

FIGS. 6A to 6C are perspective views of an exemplary electrode connecting member coupled to a flat fluorescent lamp according to a fourth exemplary embodiment of the present invention.

The fourth exemplary embodiment shown in FIGS. 6A to 6C is substantially similar to the third embodiment, except that it additionally includes a reinforcing protrusion and a second fixing unit. Hereinafter, this embodiment will be explained based on these differences.

The electrode connecting member 200 includes a first coupling unit 210, a second coupling unit 230, a first fixing unit 251, and a second fixing unit 252. The first coupling unit 210 is coupled to an end of the flat fluorescent lamp 100, and the second coupling unit 230 is assembled to the first coupling unit 210. Preferably, the first coupling unit 210 is made of insulating material, and the second coupling unit 230 is made of conductive material.

The first coupling unit 210 includes a first body 211, a first guide 216 for guiding an assembling position of the second coupling unit, a second guide 217 for guiding a coupling position of the first coupling unit 210, and a reinforcing protrusion 218.

The reinforcing protrusion 218 is formed on the first body 211 and spaced apart by a predetermined interval from the compressing portion 235 of the second coupling unit 230. The reinforcing protrusion 218 functions as a support for fixing the first fixing unit 251 more firmly.

The second coupling unit 230 includes a second body 231 arranged on the first body 211, soldering portions 236 and 237 connected to the electrode 140 of the flat fluorescent lamp 100, and a compressing portion 235 connected to an end of the wire 300 through which the power is applied to the electrode 140 of the flat fluorescent lamp 100. The second body 231 is formed with a first guide hole 238 coupled to the first guide 216 and a reinforcing protrusion hole 239 through which the reinforcing protrusion 218 passes.

The first fixing unit 251 simultaneously wraps and fixes the compressing portion 235 of the second coupling unit 230 and the wire 300 together, and the second fixing unit 252 simultaneously wraps and fixes the first fixing unit 251 and the reinforcing protrusion 218 together. The first fixing unit 251 and the second fixing unit 252 are preferably made of a flexible insulation material. In this embodiment, a thermally-shrinkable insulation tube is used as the first fixing unit 251 and the second fixing unit 252. The first fixing unit 251 is positioned to completely wrap an end of the wire 300 and the compressing portion 235. When heat is applied thereto, the first fixing unit 251 shrinks and becomes firmly secured to the wire 300 and the compressing portion 235 as shown in FIG. 6B. Then, the second fixing unit 252 is positioned to completely wrap the first fixing unit 251 and the reinforcing protrusion 218. When heat is applied thereto, the second fixing unit 252 shrinks and becomes firmly fixed to the first fixing unit 251 as shown in FIG. 6C, thereby further improving reliability of the wire connection.

According to the exemplary embodiments of the present invention as mentioned above, a wire 300 for applying power to a surface light source 100 is connected to an electrode connecting member 200 using a compressing structure, and the electrode connecting member 200 is coupled to the surface light source 100 and then soldered to an electrode 140, thereby ensuring higher stability and the better assembling workability and productivity required for mass production.

The aforementioned embodiments are only exemplary those of an electrode connecting member and a surface light source backlight unit including the same according to the present invention. Thus, the scope of the present invention is not limited to the embodiment described and illustrated above. As claimed in the appended claims, it will be apparent that those skilled in the art can make various modifications and changes thereto without departing from the scope of the invention.

What is claimed is:

1. An electrode connecting member of a surface light source backlight unit, comprising:
a first coupling unit coupled to an end of a surface light source; and
a second coupling unit assembled to the first coupling unit,
wherein the first coupling unit includes a first body; and the second connecting unit includes a second body arranged on the first body, a soldering portion connected to an electrode of the surface light source, and a compressing portion connected to a wire for applying a power to the surface light source.

2. The electrode connecting member as claimed in claim 1, wherein the first coupling unit is made of insulating material, and the second coupling unit is made of conductive material.

3. The electrode connecting member as claimed in claim 1, wherein the first body of the first coupling unit includes a groove having a predetermined width and depth, and the second body of the second coupling unit is arranged in the groove.

4. The electrode connecting member as claimed in claim 1, wherein the first body includes a first base plate, a first upper plate extending from a first end of the first base plate, and a first lower plate extending from a second end of the first base plate; and the second body includes a second base plate, a second upper plate extending from a first end of the second base plate, and a second lower plate extending from a second end of the second base plate;
the soldering portion includes a first soldering portion and a second soldering portion, the soldering portion extending from respective ends of the second upper and lower plates of the second body; and
the compressing portion extends from a side of the second base plate of the second body.

5. The electrode connecting member as claimed in claim 1, wherein the first coupling unit further includes a first guide protruded from the first body guiding an assembling position of the second coupling unit, and the second coupling unit includes a first guide hole for receiving the first guide.

6. The electrode connecting member as claimed in claim 1, wherein the first coupling unit further includes a second guide formed at a side of the first body, the second guide guiding a coupling position of the surface light source and the first coupling unit; and
the second guide extends laterally from the side of the first body; and wherein an end of the second guide bends upward at an angle to face the side of the surface light source.

7. The electrode connecting member as claimed in claim 1, further comprising a first fixing unit simultaneously wrapping and fixing the wire together with the compressing portion of the second coupling unit.

8. The electrode connecting member as claimed in claim 7, wherein the first coupling unit further includes a reinforcing protrusion preparing a support for fixing the first fixing unit, and the second coupling unit including a reinforcing protrusion hole for receiving the reinforcing protrusion.

9. The electrode connecting member as claimed in claim 8, further comprising a second fixing unit simultaneously wrapping and fixing the first fixing unit together with the reinforcing protrusion.

10. The electrode connecting member as claimed in claim 9, wherein the first fixing unit and the second fixing unit are made of a flexible insulation material.

11. A surface light source backlight unit, comprising:
a surface light source; and
at least one electrode connecting member connecting an electrode of the surface light source to a wire for applying a power to the surface light source,
wherein the electrode connecting member comprises a first coupling unit coupled to an end of the surface light source; and a second coupling unit assembled to the first coupling unit; wherein the first coupling unit includes a first body; and the second connecting unit includes a second body arranged on the first body, a soldering portion connected to an electrode of the surface light source, and a compressing portion connected to the wire for applying a power to the surface light source, and
the surface light source includes a flat fluorescent lamp, the flat fluorescent lamp including a first substrate in which a plurality of discharge spaces are formed, a second substrate facing the first substrate, a sealing member for attaching the first and second substrates, and the electrode disposed on an end of the flat fluorescent lamp for applying a power.

12. The surface light source backlight unit as claimed in claim 11, wherein the first coupling unit is made of insulating material, and the second coupling unit is made of conductive material.

13. The surface light source backlight unit as claimed in claim 11, wherein the first body of the first coupling unit includes a groove having a predetermined width and depth, and the second body of the second coupling unit is arranged in the groove.

14. The surface light source backlight unit as claimed in claim 11, wherein the first body includes a first base plate, a first upper plate extending from a first end of the first base plate, and a first lower plate extending from a second end of the first base plate; and the second body includes a second base plate, a second upper plate extending from a first end of the second base plate, and a second lower plate extending from a second end of the second base plate;
the first base plate of the first body is shaped corresponding to a side surface of the surface light source; the first upper plate is shaped corresponding to a surface of the first substrate of the surface light source; and the first lower plate is shaped corresponding to a surface of the second substrate of the surface light source; and
the second base and the upper and lower plates of the second body are respectively shaped corresponding to the first base and the upper and lower plates of the first body.

15. The surface light source backlight unit as claimed in claim 11, wherein the first coupling unit further includes a first guide protruded from the first body guiding an assembling position of the second coupling unit, and the second coupling unit includes a first guide hole for receiving the first guide.

16. The surface light source backlight unit as claimed in claim 11, wherein the first coupling unit further includes a second guide formed at a said of the first body, the second guide guiding a coupling position of the surface light source and the first coupling unit; and
the second guide extends laterally from the side of the first body; and wherein an end of the second guide bends upward at an angle to face the side of the surface light source.

17. The surface light source backlight unit as claimed in claim 11, further comprising a first fixing unit simultaneously wrapping and fixing the wire together with the compressing portion of the second coupling unit.

18. The surface light source backlight unit as claimed in claim 17, wherein the first coupling unit further includes a reinforcing protrusion preparing a support for fixing the first fixing unit, and the second coupling unit includes a reinforcing protrusion hole for receiving the reinforcing protrusion.

19. The surface light source backlight unit as claimed in claim 18, further comprising a second fixing unit simultaneously wrapping and fixing the first fixing unit together with the reinforcing protrusion.

20. The surface light source backlight unit as claimed in claim 19, wherein the first fixing unit and the second fixing unit are made of a flexible insulation material.
